(19) United States
(12) Patent Application Publication
(10) Pub. No.: US 2007/0221624 A1
(43) Pub. Date: Sep. 27, 2007

(54) ELECTRON EMISSION DEVICE, METHOD OF MANUFACTURING THE ELECTRON EMISSION DEVICE, AND ELECTRON EMISSION DISPLAY USING THE ELECTRON EMISSION DEVICE

(76) Inventors: Sang-Hyuck Ahn, Yongin-si (KR); Sang-Jo Lee, Yongin-si (KR); Byung-Gil Jea, Yongin-si (KR); Sang-Ho Jeon, Yongin-si (KR); Jin-Hui Cho, Yongin-si (KR); Su-Bong Hong, Yongin-si (KR)

Correspondence Address: CHRISTIE, PARKER & HALE, LLP, PO BOX 7068, PASADENA, CA, 91109-7068, US

(21) Appl. No.: 11/686,316

(22) Filed: Mar. 14, 2007

(30) Foreign Application Priority Data
Mar. 23, 2006 (KR) 10-2006-0026524

(51) Int. Cl. B44C 1/22; H01L 33/00

(52) U.S. Cl. 216/83; 257/79; 257/89; 216/95; 216/89

(57) ABSTRACT

An electron emission device including a first electrode, an electron emission region formed on the first electrode, and a second electrode disposed on the first electrode with an insulating layer interposed between the first and second electrodes. The insulating layer and the second electrode are provided with openings for exposing the electron emission region. A method of manufacturing includes forming a mask layer having an opening on the second electrode, forming the opening of the second electrode by etching the second electrode using the mask layer, forming the opening in the insulating layer by wet-etching the insulating layer, the opening in the insulating layer having an upper width greater than that of the opening in the second electrode, enlarging the opening in the second electrode by etching an exposed portion of the second electrode to correspond to the opening in the insulating layer, and removing the mask layer.

### CROSS-REFERENCE TO RELATED APPLICATION

This application claims priority to and the benefit of Korean Patent Application No. 10-2006-0026524 filed on Mar. 23, 2006 in the Korean Intellectual Property Office, the entire content of which is incorporated herein by reference.

### BACKGROUND OF THE INVENTION

1. Field of the Invention

The present invention relates to an electron emission device, and more particularly, to an electron emission device having openings formed through a second electrode and an insulating layer, a method of manufacturing the electron emission device, and an electron emission display having the electron emission device.

2. Description of Related Art

A typical electron emission device using Field Emission Array (FEA) elements includes a first substrate on which first electrodes, an insulating layer, and second electrodes are successively formed. Openings are formed through the second electrodes and the insulating layer at each crossed region of the first and second electrodes to partly expose the surfaces of the first electrodes. The electron emission regions are formed on the exposed surfaces of the first electrodes through these openings.

These openings are usually formed through the second electrodes and the insulating layer through a wet-etching process using a mask layer. In this process, a mask layer is formed on the substrate and covers the second electrodes. Openings in the mask layer expose portions of the second electrodes. These exposed portions are etched to form the openings in the second electrodes. Then, the portions of the insulating layer that are exposed by the openings in the second electrodes are etched to form the openings in the insulating layer.

The second electrodes have a thickness in the range of thousands of angstrom (Å) while the insulating layer has a thickness of several micrometers (μm). In addition, the upper widths (or diameters) of the openings in the insulating layer increase as the etching depth increases due to the isotropic nature of the wet-etching process. As a result, when the wet-etching process is finished, the upper widths of the openings in the insulating layer, on which the second electrode is formed, become greater than those of the corresponding openings in the second electrodes.

Therefore, portions of the second electrodes may be suspended above the openings in the insulating layer, thereby decreasing shape stability and pattern preciseness. In addition, in the course of forming the electron emission regions through the openings of the insulating layer, the portions of the second electrodes that lie above the openings in the insulating layer, may be broken away. When the broken pieces contact the electron emission regions or the first electrodes, a short circuit may occur between the first and second electrodes. This may cause product defectiveness.

### SUMMARY OF THE INVENTION

One embodiment of the present invention provides an electron emission device in which openings formed through a second electrode are precisely aligned with corresponding openings formed through an insulating layer, a method of manufacturing the electron emission device, and an electron emission display including the electron emission device.

According to an embodiment of the present invention, a method is provided for manufacturing an electron emission device including a first electrode disposed on a first substrate, an electron emission region disposed on the first electrode, and a second electrode disposed on the first electrode with an insulating layer interposed between the first and second electrodes, the insulating layer and the second electrode being provided with openings for exposing the electron emission region, the method including forming a mask layer having an opening on the second electrode; forming the opening in the second electrode by etching the second electrode using the mask layer; forming the opening in the insulating layer by wet-etching the insulating layer wherein a width of the opening in the insulating layer at an upper portion is greater than a width of the opening in the second electrode; enlarging the opening in the second electrode by etching an exposed portion of the second electrode exposed to the opening in the insulating layer; and removing the mask layer.

The etching of the exposed portion of the second electrode may be a wet-etching performed by filling the opening in the insulating layer with a first etching solution for etching the second electrode.

After the opening in the second electrode is enlarged by etching the exposed portion of the second electrode, the width of the opening in the second electrode may be greater than the width of the opening in the insulating layer.

The first electrode may be formed of a conductive material having a corrosion-resistance against the first etching solution.

The method may further include, after the removing of the mask layer, forming the electron emission region on the first electrode, wherein the electron emission region is formed of a material selected from the group consisting of carbon nanotubes, graphite, graphite nanofibers, diamonds, diamond-like carbon, C₆₀, silicon nanowires, and combinations thereof.

In one embodiment, there is provided an electron emission device manufactured by the above-described method, wherein a distance between a center of the opening in the insulating layer and a center of the opening in the second electrode is less than 0.5 μm.

According to still another embodiment, there is provided an electron emission display including: an electron emission device manufactured by the above-described method, a second substrate facing the first substrate with a vacuum region formed between the first and second substrates, and phosphor layers disposed on a surface of the second substrate facing the first substrate, an anode electrode disposed on the phosphor layers, wherein a distance between a center of the opening in the insulating layer and a center of the opening in the second electrode is less than 0.5 μm.

In another embodiment, there is provided a method of manufacturing an electron emission device including a first electrode disposed on a first substrate, an electron emission region disposed on the first electrode, a second electrode disposed on the first electrode with a first insulating layer interposed between the first and second electrodes, and a third electrode disposed on the second electrode with a second insulating layer interposed between the second and third electrodes, wherein the first insulating layer, the second electrode, the second insulating layer, and the third electrode are provided with openings for exposing the electron emission region, the method including: forming a first mask layer having an opening on the third electrode; forming the opening in the third electrode by etching the third electrode using the first mask layer; forming the opening in the second insulating layer by wet-etching the second insulating layer, wherein a width of the opening in the second insulating layer at an upper portion is greater than a width of the opening in the third electrode; enlarging the opening in the third electrode by etching an exposed portion of the third electrode exposed to the opening in the second insulating layer; removing the first mask layer; forming a second mask layer having an opening on the second electrode; and forming the opening in the second electrode by etching the second electrode using the second mask layer.

The method may further include: forming the opening in the first insulating layer by wet-etching the first insulating layer, wherein a width of the opening in the first insulating layer at an upper portion is greater than a width of the opening in the second electrode; enlarging the opening in the second electrode by etching an exposed portion of the second electrode exposed to the opening in the first insulating layer; and removing the second mask layer.

The etching of the exposed portion of the third electrode may be a wet-etching performed by filling the opening in the second insulating layer with a second etching solution for etching the third electrode.

After the opening in the third electrode is enlarged by etching the exposed portion of the third electrode, a width of the opening in the third electrode may be greater than a width of the opening in the second insulating layer.

The second electrode may be formed of a conductive material having a corrosion-resistance against the second etching solution.

According to yet another embodiment of the present invention, there is provided an electron emission device manufactured by the above method, wherein a distance between a center of the opening in the second insulating layer and a center of the opening in the third electrode may be less than 0.5 μm.

According to yet another embodiment of the present invention, there is provided an electron emission display, including: an electron emission device manufactured by the above method; a second substrate facing the first substrate with a vacuum region formed between the first and second substrates; and phosphor layers disposed on a surface of the second substrate facing the first substrate; and an anode electrode disposed on the phosphor layers, wherein a distance between a center of the opening in the second insulating layer and a center of the opening in the third electrode is less than 0.5 μm.

### BRIEF DESCRIPTION OF THE DRAWINGS

The accompanying drawings, together with the specification, illustrate exemplary embodiments of the present invention, and, together with the description, serve to explain the principles of the present invention.

FIGS. 1A, 1B, 1C, 1D, 1E, and 1F are sectional views illustrating a method of manufacturing an electron emission device according to an embodiment of the present invention;

FIG. 2 is a photograph taken by a scanning electron microscope of the electron emission device manufactured according to the method depicted in FIGS. 1A through 1F;

FIG. 3 is a partial exploded perspective view of an electron emission display having the electron emission device manufactured according to the method depicted in FIGS. 1A through 1F;

FIG. 4 is a partial sectional view of the electron emission display of FIGS. 1A through 1F;

FIGS. 5A, 5B, 5C, 5D, 5E, 5F, 5G, 5H, 51, and 5J are sectional views illustrating a method of manufacturing an electron emission device according to another embodiment of the present invention;

FIG. 6 is a partial exploded perspective view of an electron emission display having the electron emission device manufactured according to the method depicted in FIGS. 5A through 5J; and

FIG. 7 is a partial sectional view of the electron emission display of FIG. 6.

### DETAILED DESCRIPTION

In the following description, only certain exemplary embodiments of the present invention are shown and described, by way of illustration. As those skilled in the art would recognize, the described exemplary embodiments may be modified in various ways, all without departing from the spirit or scope of the present invention. Accordingly, the drawings and description are to be regarded as illustrative in nature, and not restrictive.

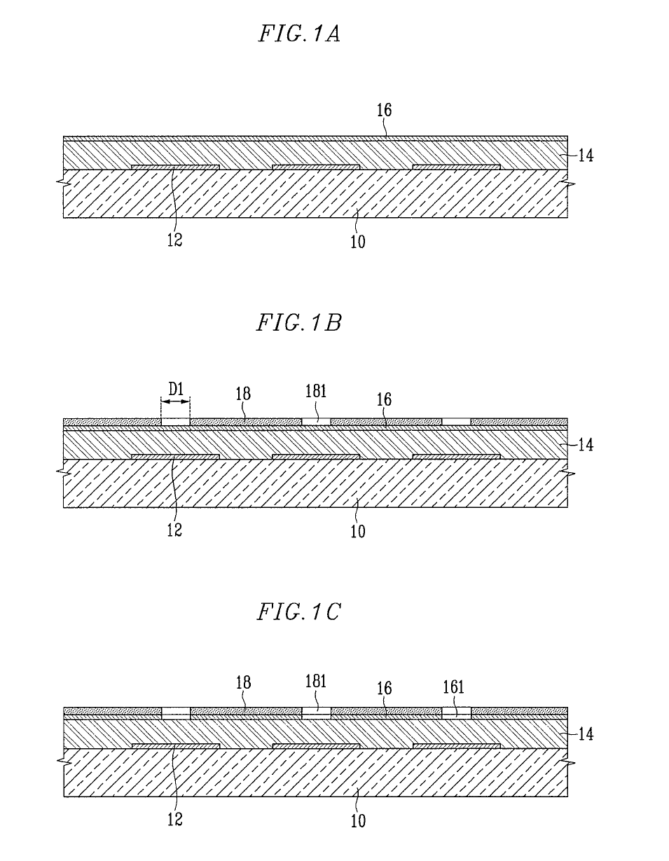

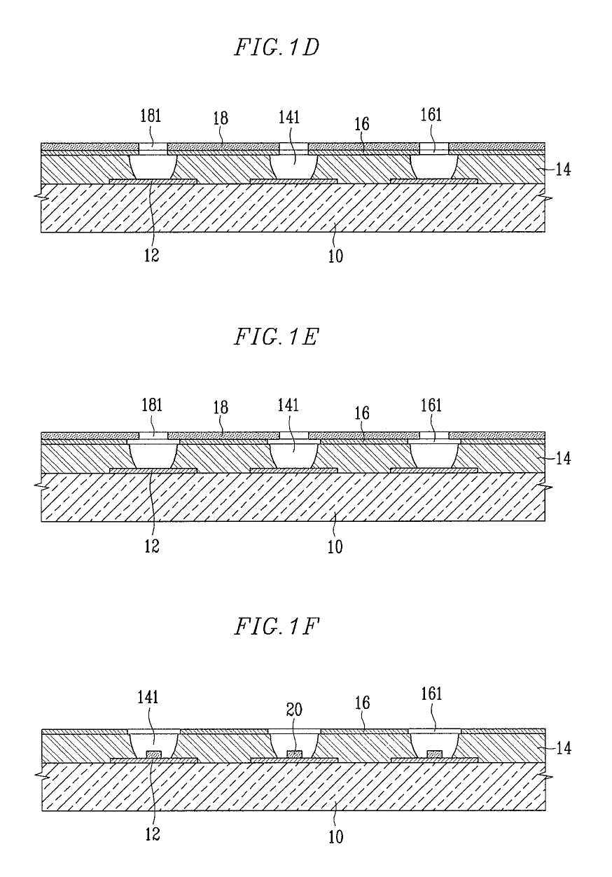

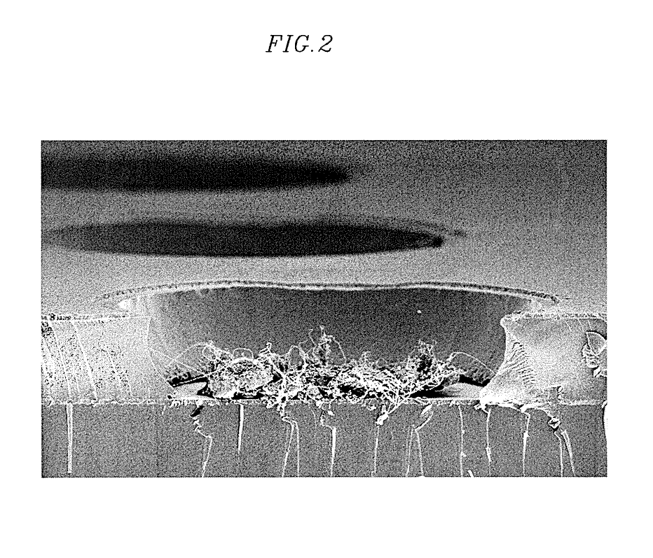

Referring first to FIG. 1A, a conductive layer is formed on a substrate 10 and processed to form first electrodes 12 having a stripe pattern. An insulating material is deposited on the substrate 10 to cover the first electrodes 12 to form an insulating layer 14 having a certain (e.g., predetermined) thickness. The insulating layer 14 is formed by repeating screen-printing, drying and firing processes one or more times. The thickness of the insulating layer 14 may be within a range of about 3-5 μm.

Another conductive layer is formed on the insulating layer 14 and processed to form second electrodes 16 having a stripe pattern crossing the first electrodes 12 at right angles. The first electrodes 12 may be formed of a transparent material such as indium tin oxide (ITO) while the second electrodes 16 may be formed of a metal material such as Chromium (Cr) or Molybdenum (Mo).

Referring to FIG.1 B, a mask layer 18 is formed on the substrate 10 to cover the insulating layer 14 and the second electrodes 16 and is processed to have openings 181, each having a specific width (or diameter) D1. The mask layer 18 may be photoresist layer, and the openings 181 in the mask layer 18 may be formed by partial light exposing and developing processes.

Referring to FIG. 1C, the portions of the second electrodes 16 exposed by the openings 181 in the mask layer 18 are removed using a first etching solution to form openings 161. The width of each of the openings 161 in the second electrodes 16 is identical to the width D1 of the corresponding opening in the mask layer 18.

Referring to FIG. 1D, in a state where the mask layer 18 is still maintained, to form openings 141 in the insulating layer 14, portions of the insulating layer 14 exposed by the openings 161 in the second electrodes 16 are removed using a second etching solution.

At this point, since the upper widths of the openings 141 in the insulating layer 14 gradually increase as the etching depths increase due to the isotropic nature of the wet-etching process, the upper widths of the openings 141 in the insulating layer 14, on which the second electrodes 16 are formed, become greater than those of each of the corresponding openings 161 in the second electrodes 16. Therefore, portions of the second electrodes 16 may be suspended above the openings 141 in the insulating layer 14, thereby decreasing shape stability and pattern preciseness.

Referring to FIG.1 E, the portions of the second electrodes 16 suspended above the openings 141 in the insulating layer 14 are removed through an etching process using the first etching solution. This etching process is performed by dipping the current substrate structure in the first etching solution. As a result, the openings 141 in the insulating layer 14 are filled with the first etching solution. The suspended portions of the second electrodes 16 are thus removed by the etching solution that fills the openings 141.

At this point, by controlling the dipping time of the substrate structure in the first etching solution, the widths of the openings 161 in the second electrodes 16 can be adjusted. That is, when the dipping time is relatively long, the first etching solution permeates between the mask layer 18 and the insulating layer 14 to etch the openings 161 in the second electrodes 16 such that the widths of the openings 161 in the second electrodes 16 are greater than those of the corresponding openings 141 in the insulating layer 14.

In the above process, since portions of the first electrodes 12 are exposed to the first etching solution, the first electrodes 12 are formed of a material different from that of the second electrodes 16. That is, the first electrodes 12 are formed of a material having a corrosion-resistance against the first etching solution so as not to be etched when the second electrodes 16 are etched.

Next, the mask layer 18 is removed and, as shown in FIG. 1F, electron emission regions 20 are formed on the exposed portions of the first electrodes 12 through the openings 141 in the insulating layer 14.

The electron emission regions 20 may be formed of a material such as a carbonaceous material or a nanometer-sized material. For example, the electron emission regions 20 can be formed of a material selected from the group consisting of carbon nanotubes, graphite, graphite nanofibers, diamonds, diamond-like carbon, C₆₀, silicon nanowires, and combinations thereof.

The electron emission regions 20 can be formed by preparing a paste mixture by mixing vehicles, binder and the like, screen-printing the paste mixture on the exposed portions of the first electrodes 12, and drying and firing the printed mixture.

The first electrodes 12 may be cathode electrodes for applying electric current to the electron emission regions 20 while the second electrodes 16 may be gate electrodes for inducing electron emission by forming an electric field around the electron emission regions.

As described above, since the second electrodes 16 are etched again after the openings 141 of the insulating layer 14 are formed, no portion of the second electrodes 16 is suspended above the openings 141 in the insulating layer 14. As a result, the shape stability of the second electrodes 16 can be improved and a short circuit between the first and second electrodes 12 and 16 can be prevented during the forming of the electron emission regions 20.

In addition, referring to FIGS. 1A-1F, because only one mask layer 18 is used, the process can be simplified and the sizes of the openings 161 in the second electrodes 16 can be identical to the openings 141 in the insulating layer 14. In addition, pattern preciseness of the second electrodes 16 is improved. Furthermore, by using the above-described method, the openings 161 and 141 can be formed to be relatively small-sized.

FIG. 2 shows a photograph taken by a scanning electron microscope of the electron emission device manufactured according to the method depicted in FIGS. 1A through 1F.

In the electron emission device shown in FIG. 2, the distance between the center of the opening in the second electrode and the center of the opening in the insulating layer is less than 0.5 μm. Further the width (or diameter) of the opening in the second electrode is greater than that of the corresponding opening in the insulating layer. A difference between the upper circumference of the opening in the second electrode and the upper circumference of the corresponding opening in the insulating layer is less than 1 μm.

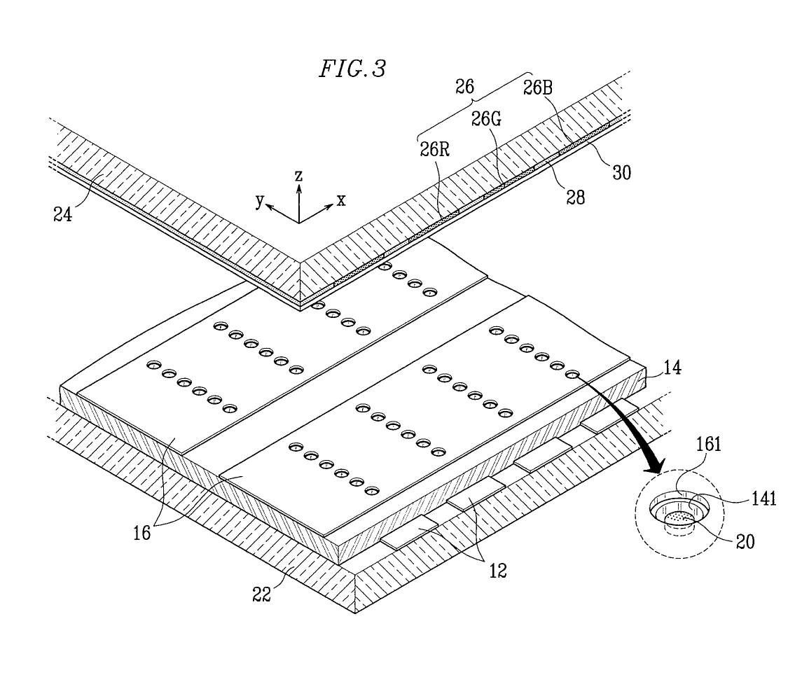

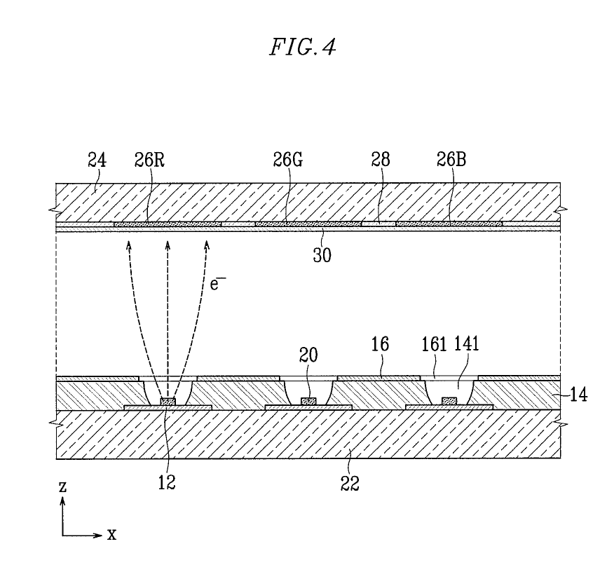

Referring to FIGS. 3 and 4, an electron emission display according to an embodiment of the present invention manufactured by the above discussed method includes first and second substrates 22 and 24 facing each other and spaced apart by a certain (e.g., predetermined) distance. A sealing member (not shown) is provided at the peripheries of the first and the second substrates 22 and 24 to seal them together, thereby forming an envelope. The interior of the envelope is exhausted to be kept at a degree of vacuum of about 10⁻⁶ Torr.

The first electrodes 12 are formed on the first substrate 22 and the insulating layer 14 is formed on the first substrate 22 to fully cover the first electrodes 12. The second electrodes 16 are formed on the insulating layer 14, crossing the first electrodes 12 at right angles. The openings 161 and 141 are formed respectively through the insulating layer 14 and the second electrodes 16 at each crossed region of the first and second electrodes 12 and 16 to expose the electron emission regions 20.

At this point, the openings 161 and 141 are formed in the second electrodes 16 and the insulating layer 14, respectively, using the above described method illustrated with reference to FIGS. 1A through 1F. Therefore, the distance between the center of each of the openings 161 in the second electrodes 16 and the center of the corresponding opening 141 in the insulating layer 14 is less than 0.5 μm. In addition, the difference between an upper circumference of each of the openings 161 in the second electrode 16 and the upper circumference of the corresponding opening 141 in the insulating layer 14 is less than 1 μm.

Phosphor layers 26 such as red (R), green (G) and blue (B) phosphor layers 26R, 26G and 26B are formed on a surface of the second substrate 24 opposite to the first substrate 22, and black layers 28 are arranged between the phosphor layers 26. Each crossed region of the first and second electrodes 12 and 16 corresponds to a single color phosphor and define a pixel region.

An anode electrode 30 is formed of a conductive material such as aluminum, and is formed on the phosphor and black layers 26 and 28. The anode electrode 30 increases the screen luminance by receiving the high voltage required to accelerate the electron beams traveling from the first substrate 22 toward the second substrate 24 and by reflecting the visible light rays radiated from the phosphor layer 26, toward the first substrate 22 to the second substrate 24, thereby increasing the screen's luminance.

Disposed between the first and second substrates 22 and 24 are spacers (not shown) for uniformly maintaining a gap against outer forces between the first and second substrates 22 and 24. The spacers are arranged on the black layers 28 and do not trespass onto the phosphor layers 26.

The above-described electron emission display is driven when a certain (e.g., predetermined) voltage is applied to the first, second and anode electrodes 12, 16 and 30.

For example, referring to FIG. 4, one of the first and second electrodes 12 and 16 serves as scan electrodes receiving a scan driving voltage and the other electrodes function as data electrodes receiving a data driving voltage. The anode electrode 30 receives a DC voltage capable of accelerating the electron beams (e.g., a DC voltage of hundreds through thousands of volts).

Electric fields are formed around the electron emission regions 20 of pixels where a voltage difference between the first and second electrodes 12 and 16 is equal to or greater than a threshold value, and thus, the electrons are emitted from the electron emission regions 20. The high voltage applied to the anode electrode 30 causes the emitted electrons to strike the phosphor layers 26 of the corresponding pixel, thereby exciting the phosphor layers 26.

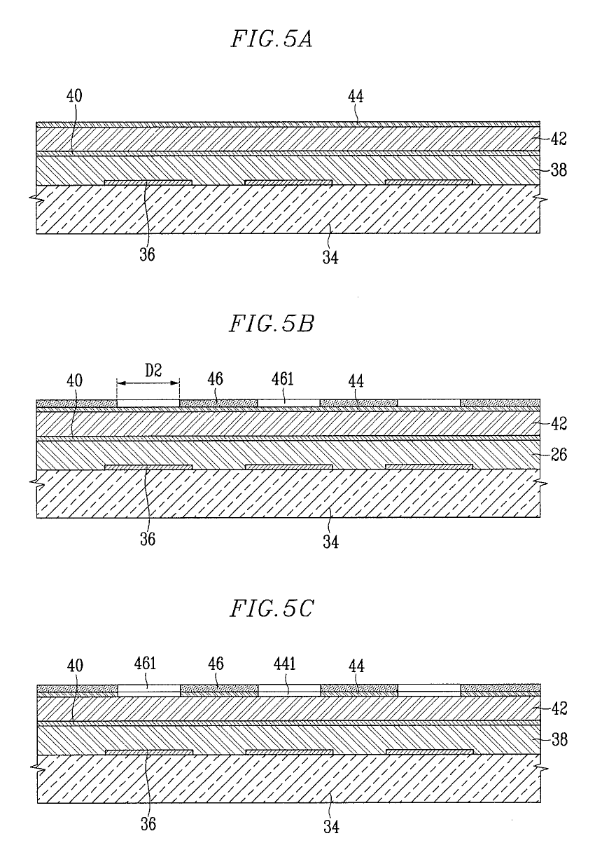

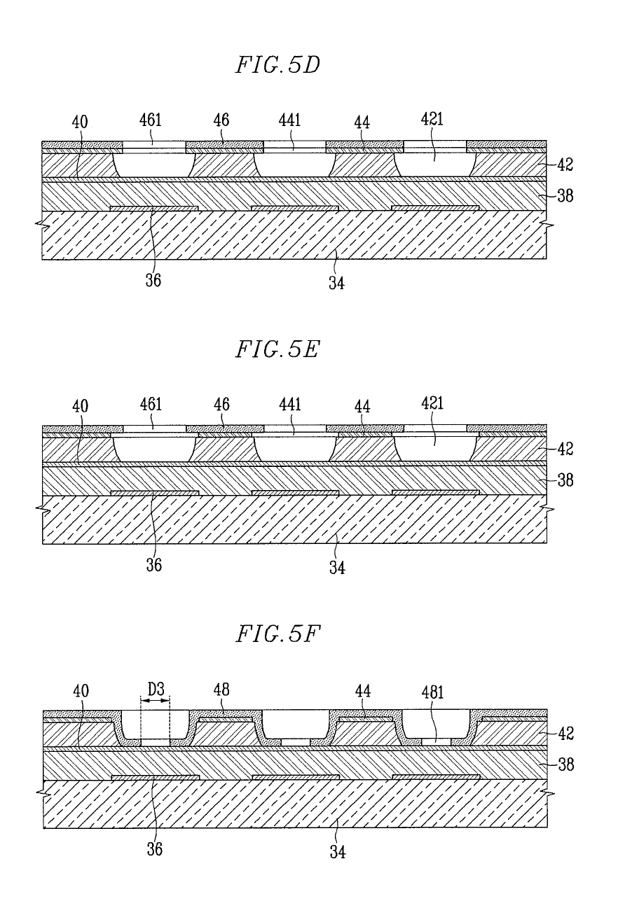

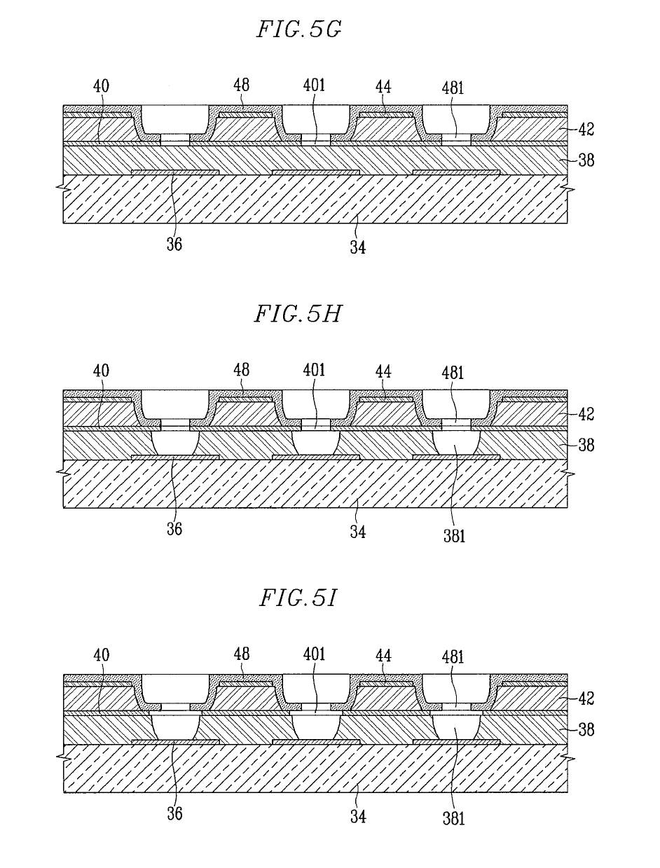

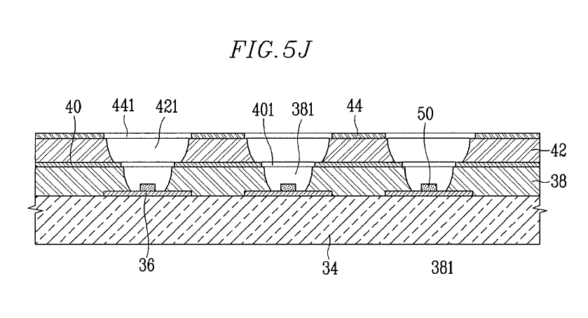

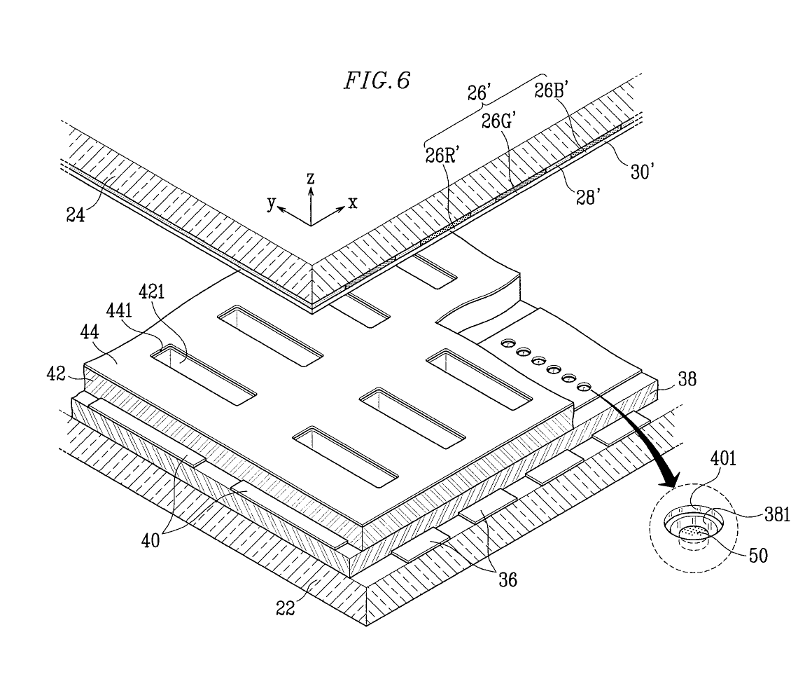

Referring to FIG. 5A, a conductive layer is formed on a substrate 34 and processed to form first electrodes 36 having a stripe pattern. An insulating material is deposited on the substrate 34 to cover the first electrodes 36 to form a first insulating layer 38.

Another conductive layer is formed on the first insulating layer 38 and processed to form second electrodes 40 having a stripe pattern crossing the first electrodes 36 at right angles. Another insulating material is deposited on the first insulating layer 38 to cover the second electrodes 40 to form a second insulating layer 42. Another conductive layer is formed on the second insulating layer 42 to form a third electrode 44.

Referring to FIG. 5B, a first mask layer 46 is formed on the third electrode 44 and processed to form openings 461, each having a width (or diameter) D2.

Referring to FIG. 5C, portions of the third electrode 44 exposed by the openings 461 in the first mask layer 46 are removed using a first etching solution to form openings 441. The width (or diameter) of each opening 441 in the third electrode 44 is identical to the width (or diameter) D2 of the openings 461 in the first mask layer 46.

Referring to FIG. 5D, in a state where the first mask layer 46 is still maintained, portions of the second insulating layer 42 exposed by the openings 441 in the third electrode 44 are removed using a second etching solution to form openings 421. At this point, since the upper widths of the openings 421 in the second insulating layer 42 gradually increase as the etching depths increase due to the isotropic nature of the wet-etching process, the upper width of each of the openings 421 in the second insulating layer 42, on which the third electrode 44 is formed, becomes greater than that of the corresponding opening 441 in the third electrode 44. Therefore, a portion of the third electrode 44 may be suspended above the openings 421 in the second insulating layer 42, thereby decreasing shape stability and pattern preciseness.

Referring to FIG. 5E, the suspended portions of the third electrodes 44 above the openings 421 are removed through an etching process using the first etching solution. This etching process is performed by dipping the current substrate structure in the first etching solution. Then, the openings 421 in the second insulating layer 42 are filled with the first etching solution, and thus, the suspended portions of the third electrodes 44 are removed by the first etching solution filled in the openings 421. Therefore, the widths (or diameters) of the openings 441 in the third electrode 44 are precisely formed to be equal to or greater than those of the corresponding openings 421 in the second insulating layer 42. This third electrode 44 functions as a focusing electrode for focusing electron beams.

In the above process, since portions of the second electrodes 40 are exposed to the first etching solution, the second electrodes 40 are formed of a material different from that of the third electrodes 44. That is, the second electrodes 40 are formed of a material having a corrosion-resistance against the first etching solution so as not to be etched when the third electrodes 44 are etched.

Next, the first mask layer 46 is removed and, referring to FIG. 5F, a second mask layer 48 is formed on the substrate 34 and processed to form openings 481 each having a width (or diameter) D3 and exposing a portion of the second electrodes 40.

Referring to FIG. 5G, the portions of the second electrodes 40 exposed by the openings 481 in the second mask layer 48 are removed by a third etching solution to form openings 401. The width (or diameter) of each of the openings 401 is identical to that of the corresponding opening 481 in the second mask layer 48. At this point, the widths of the openings 481 in the second mask layer 48 and the widths of the openings 401 in the second electrodes 40 may be smaller than the lower widths of the openings 421 in the second insulating layer 42.

Referring to FIG. 5H, in a state where the second mask layer 48 is still maintained, the portions of the first insulating layer 38 exposed by the openings 401 in the second electrodes 40 are removed by a fourth etching solution to form openings 381. Likewise, at this point, since the upper widths (or diameters) of the openings 381 in the first insulating layer 38 gradually increase as the depths increase due to the isotropic nature of the wet-etching process, the upper width (or diameter) of each of the openings 381 in the first insulating layer 38, on which the second electrodes 40 are formed, becomes greater than that of the corresponding opening 401 in the second electrodes 40.

Referring to FIG. 51, the current substrate structure is dipped in the third etching solution to remove the portions of the second electrodes 40 exposed to the openings 381 in the first insulating layer 38. By this secondary etching process for the second electrodes 40, the widths (or diameters) of the openings 401 in the second electrodes 40 are precisely formed to be equal to or greater than those of the openings 381 in the first insulating layer 38.

In the above process, since portions of the first electrodes 36 are exposed to the third etching solution, the first electrodes 36 can be formed of a material different from that of the second electrodes 40. That is, the first electrodes 36 can be formed of a material having a corrosion-resistance against the third etching solution so as not to be etched when the second electrodes 40 are etched.

Next, the second mask layer 48 are removed and, referring now to FIG. 5J, electron emission regions 50 are formed on the first electrodes 36 through the openings 381 in the first insulating layer 38. The material and manufacturing method of the electron emission regions 50 are identical to those of the foregoing embodiment.

According to this embodiment, since the third electrodes 44 are secondarily etched after the openings 421 in the second insulating layer 42 are formed and the second electrodes 40 are secondarily etched after the openings 381 in the first insulating layer 38 are formed, the shape stability of the third and second electrodes 44 and 40 can be improved and the shape preciseness of the openings 441 and 401 can also be improved.

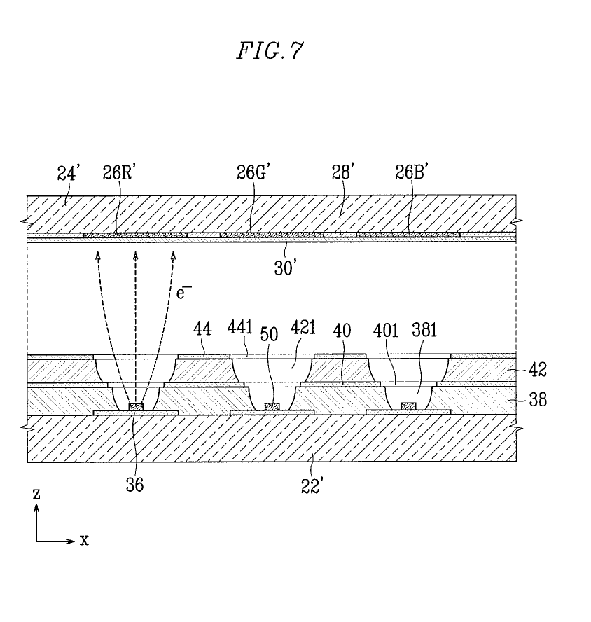

FIGS. 6 and 7 show an electron emission display having the electron emission device manufactured according to the method illustrated with reference to FIGS. 5A through 5J.

An electron emission display according to this embodiment of the present invention includes first and second substrates 22′ and 24′ facing each other and spaced apart by a certain (e.g., predetermined) distance. A sealing member (not shown) is provided at the peripheries of the first and the second substrates 22′ and 24′ to seal them together.

The first insulating layer 38 is formed on the first substrate 22′ to cover the first electrodes 36 and the second insulating layer 42 is formed on the first insulating layer 38 to cover the second electrodes 40. The third electrode 44 is formed on the second insulating layer 42.

One opening 441 is formed on the third electrode 44 at each crossed region of the first and second electrodes 36 and 40 to generally focus the electrodes emitted from one pixel region. Alternatively, one opening is formed on the third electrode 44 to correspond to one electron emission region 50 to individually focus the electrons emitted from one electron emission region 50. The former is applied to this embodiment.

The third electrode 44 receives 0V or a negative DC voltage of several to tens of volts. Therefore, the third electrode 44 converges the electrons to a central portion of bunched electron beams by applying repulsive force to the electrons.

As the method depicted in FIGS. 1A through 1J is applied to manufacture the electron emission display, the distance between the center of each of the openings 441 in the third electrode 44 and the center of the corresponding opening 421 in the second insulating layer 42 is less than 0.5 μm. That is, the centers of the openings 441 and 421 are almost coincident with each other. The distance between the center of each of the openings 401 in the second electrodes 40 and the center of the corresponding opening 381 in the first insulating layer 38 is also less than 0.5 μm. That is, the centers of the openings 401 and 381 are almost coincident with each other.

In addition, the difference between the upper circumference of each of the openings 441 in the third electrode 441 and the upper circumference of the corresponding opening 421 in the second insulating layer 42 is less than 1 μm. The difference between the upper circumference of each of the openings 401 in the second electrodes 40 and the upper circumference of the corresponding opening 381 in the first insulating layer 38 is also less than 1 μm.

While the invention has been described in connection with certain exemplary embodiments, it is to be understood by those skilled in the art that the invention is not limited to the disclosed embodiments, but, on the contrary, is intended to cover various modifications included within the spirit and scope of the appended claims and equivalents thereof.

What is claimed is:

1. A method of manufacturing an electron emission device comprising a first electrode disposed on a first substrate, an electron emission region disposed on the first electrode, and a second electrode disposed on the first electrode with an insulating layer interposed between the first and second electrodes, the insulating layer and the second electrode having respective openings for exposing the electron emission region, the method comprising:
forming a mask layer having an opening on the second electrode;
forming the opening in the second electrode by etching the second electrode using the mask layer;
forming the opening in the insulating layer by wet-etching the insulating layer wherein a width of an upper portion of the opening in the insulating layer is greater than a width of the opening in the second electrode;
enlarging the opening in the second electrode by etching an exposed portion of the second electrode exposed to the opening in the insulating layer; and
removing the mask layer.

2. The method of claim 1, wherein the etching of the exposed portion of the second electrode is a wet-etching performed by filling the opening in the insulating layer with an etching solution used for etching the second electrode.

3. The method of claim 2, wherein, after the opening in the second electrode is enlarged by etching the exposed portion of the second electrode, the width of the opening in the second electrode is greater than the width of the upper portion of the opening in the insulating layer.

4. The method of claim 2, wherein the first electrode is formed of a conductive material having a corrosion-resistance against the etching solution.

5. The method of claim 1, further comprising, after the removing of the mask layer, forming the electron emission region on the first electrode, wherein the electron emission region is formed of a material selected from the group consisting of carbon nanotubes, graphite, graphite nanofibers, diamonds, diamond-like carbon, C₆₀, silicon nanowires, and combinations thereof.

6. An electron emission device manufactured by the method of claim 1, wherein a distance between a center of the opening in the insulating layer and a center of the opening in the second electrode is less than 0.5 μm.

7. The electron emission device of claim 6, wherein the opening in the second electrode has a width greater than that of the opening in the insulating layer and a difference between an upper circumference of the opening in the insulating layer and an upper circumference of the opening in the second electrode is less than 1 μm.

8. An electron emission display, comprising:
an electron emission device manufactured by the method of claim 1;
a second substrate facing the first substrate with a vacuum region formed between the first and second substrates; and
phosphor layers disposed on a surface of the second substrate facing the first substrate;
an anode electrode disposed on the phosphor layers,
wherein a distance between a center of the opening in the insulating layer and a center of the opening in the second electrode is less than 0.5 μm.

9. The electron emission display of claim 8, wherein the opening in the second electrode has a width greater than that of the opening in the insulating layer and a difference between an upper circumference of the opening in the insulating layer and an upper circumference of the opening in the second electrode is less than 1 μm.

10. A method of manufacturing an electron emission device comprising a first electrode disposed on a first substrate, an electron emission region disposed on the first electrode, a second electrode disposed on the first electrode with a first insulating layer interposed between the first and second electrodes, and a third electrode disposed on the second electrode with a second insulating layer interposed between the second and third electrodes, wherein the first insulating layer, the second electrode, the second insulating layer, and the third electrode have respective openings for exposing the electron emission region, the method comprising:
forming a first mask layer having an opening on the third electrode;
forming the opening in the third electrode by etching the third electrode using the first mask layer;
forming the opening in the second insulating layer by wet-etching the second insulating layer, wherein a width of an upper portion of the opening in the second insulating layer is greater than a width of the opening in the third electrode;
enlarging the opening in the third electrode by etching an exposed portion of the third electrode exposed to the opening in the second insulating layer;
removing the first mask layer;
forming a second mask layer having an opening on the second electrode; and
forming the opening in the second electrode by etching the second electrode using the second mask layer.

11. The method of claim 10, further comprising:
forming the opening in the first insulating layer by wet-etching the first insulating layer, wherein a width of an upper portion of the opening in the first insulating layer is greater than a width of the opening in the second electrode;
enlarging the opening in the second electrode by etching an exposed portion of the second electrode exposed to the opening in the first insulating layer; and
removing the second mask layer.

12. The method of claim 11, wherein the etching of the exposed portion of the second electrode is a wet-etching performed by filling the opening in the first insulating layer with an etching solution for etching the second electrode.

13. The method of claim 12, wherein the first electrode is formed of a conductive material having corrosion-resistance against the etching solution.

14. The method of claim 10, wherein the etching of the exposed portion of the third electrode is a wet-etching performed by filling the opening in the second insulating layer with an etching solution for etching the third electrode.

15. The method of claim 14, wherein, after the opening in the third electrode is enlarged by etching the exposed portion of the third electrode, a width of the opening in the third electrode is greater than a width of the opening in the second insulating layer.

16. The method of claim 14, wherein the second electrode is formed of a conductive material having a corrosion-resistance against the etching solution.

17. An electron emission device manufactured by the method of claim 10, wherein a distance between a center of the opening in the second insulating layer and a center of the opening in the third electrode is less than 0.5 μm.

18. The electron emission device of claim 17, wherein the opening in the third electrode has a width greater than a width of the opening in the second insulating layer and a difference between an upper circumference of the opening in the second insulating layer and an upper circumference of the opening in the third electrode is less than 1 μm.

19. An electron emission display, comprising:
an electron emission device manufactured by the method of claim 10;
a second substrate facing the first substrate with a vacuum region formed between the first and second substrates;
phosphor layers disposed on a surface of the second substrate facing the first substrate; and
an anode electrode disposed on the phosphor layers,
wherein a distance between a center of the opening in the second insulating layer and a center of the opening in the third electrode is less than 0.5 μm.

20. The electron emission display of claim 19, wherein the opening in the third electrode has a width greater than a width of the opening in the second insulating layer and a difference between an upper circumference of the opening in the second insulating layer and an upper circumference of the opening in the third electrode is less than 1 μm.
